(19) United States
(12) Patent Application Publication
(10) Pub. No.: US 2010/0258813 A1
(43) Pub. Date: Oct. 14, 2010

(54) Light Emitting Device and Fabrication Thereof

(75) Inventors: Yeeu-Chang Lee, Chung Li (TW); Ko-Tao Lee, Chung Li (TW)

Correspondence Address: WPAT, PC;INTELLECTUAL PROPERTY ATTORNEYS, 7225 BEVERLY ST., ANNANDALE, VA, 22003, US

(73) Assignee: Chung Yuan Christian University, Chung Li (TW)

(21) Appl. No.: 12/632,206

(22) Filed: Dec. 7, 2009

(30) Foreign Application Priority Data
Dec. 5, 2008 (TW) 097147277

(51) Int. Cl. H01L 33/32; H01L 33/64

(52) U.S. Cl. 257/76; 438/46; 257/E33.025; 257/E33.075

(57) ABSTRACT

A light emitting diode of the invention via laser scribing method is used to build up the mesh texture on the backside of the sapphire of light emitting diodes. Then high reflectivity and thermal conductivity metals are deposited onto the mesh structure. Since the multiple-reflection from the texture, the light extraction efficiency will be increased. Meanwhile, the high thermal conductivity metal filled into the sapphire also lead to the better heat dissipation within the light emitting diodes, it will decrease the junction temperature and avoid the thermal effect to reduce light efficiency and the lifetime.

### BACKGROUND OF THE INVENTION

1. Field of the Invention

The present invention relates a fabrication of light emitting diode to enhance the brightness and increase the lifetime.

2. Description of the Related Art

The conventional light emitting diode (LED) comprises a semiconductor substrate, an illumination structure on the semiconductor substrate and two ohmic contact electrodes. The illumination structure generally is formed by multilayered Group III-V compound semiconductor layer containing aluminum. For example, AlGaAs can emit infrared light and red light, or AlGaInP can emit yellow-green light, yellow light and red light. Presently, the worldwide industry has developed several kinds of LED with different wavelengths from infrared to blue. There are also LEDs with wavelengths from purple to ultraviolet. In recently years, the most attractive development is coating the light emitting diode with phosphor that converts blue light to white light.

Most white LEDs in production today are usually fabricated by coating yellowish phosphor on a blue LED, which is near ultraviolet with wavelength around 450-470 nm. The yellow fluorescent usually made of cerium-doped yttrium aluminum garnet (Ce³⁺:YAG) crystals which have been powdered and mixed with viscous adhesive. When the blue light emitted from the LED chip, part of the blue light is efficiently converted to yellow light with broader spectrum (the spectrum centered at about 580 nm) by the Ce³⁺:YAG. Since receptors of red and green in human eyes are stimulated by yellow light, the mixture of yellow and blue light gives the appearance of white, the resulting shade often called “lunar white”. The color of yellowish emission can be tuned by substituting the cerium (Ce), doped in Ce³⁺:YAG, with other rare metal such as terbium (Tb) or gadolinium (Gd), and can even be further adjusted by substituting some or all of the aluminum in the YAG.

There are many technologies can enhance emitting efficiency of blue diodes. Roughened surface of diode can reduce the reflection issue, whereby increase emitting angle of the diode. Current that crowded along mesa edge and under electrode can be dispersed uniformly by forming a transparent conductive layer. Forming pattern on sapphire substrate by etching process before epitaxy can improve epitaxial quality and enhance emitting efficiency by multi-reflecting microstructure, which is formed between GaN and Sapphire. Therefore, common methods to improve light extraction efficiency and epitaxial quality are usually processed on the surface of light emitting diode and formal direction of sapphire.

Besides improving light characteristic and epitaxial quality, decreasing the temperature of quantum well region is also an important issue. The quantum well is a light-generating region. Therefore, decrease the temperature of quantum well can prolong the LED lifetime and avoid the thermal effect to reduce light efficiency. Due to its poor thermal conductivity (have a thermal conductivity coefficient around 42 W/m·K at 20° C.), the sapphire substrate can not appropriately dissipate heat that generated by photoelectric effect. Internal junction temperature in LED will be raised during operation time. Over-high temperature in lighting region of LED can reduce its emitting efficiency and lifetime.

### SUMMARY OF THE INVENTION

One object of the present invention is to provide a light emitting diode so as to achieve industrial demands and improve above issues caused by conventional LEDs.

The present invention primarily discloses a fabrication to improve LED structure by building up a mesh texture on the backside of a transparent substrate of LED. The light extraction efficiency will be increased due to the multiple-reflection from the texture. The LED comprises a pn-junction semiconductor layer, a mesh substrate, and a thermal dissipation layer. The pn-junction semiconductor layer comprises a p-type electrode and an n-type electrode arranged in parallel on said pn-junction semiconductor layer. The material of said pn-junction semiconductor is gallium nitride (GaN) or indium gallium nitride (InGaN). The thickness of the mesh substrate is greater than or equal to one-sixth of the thickness of light-emitting wavelength, wherein the mesh substrate is under the pn-junction semiconductor layer and caused multiple-reflection. Moreover, the thermal dissipation layer disposed under the mesh substrate to dissipate heat generated by emitted light. The major material of the thermal dissipation layer 300 is copper (Cu) which has very high thermal conductivity.

The present invention increased light extraction efficiency by the mesh substrate. The mesh substrate comprises a mesh layer and a metallic capping layer. The mesh layer is made of transparent medium such as Si, LaAlO₃, LiGaO₂, GaN, SiC, sapphire (Al₂O₃) or diamond and with a plurality of cavities spread on the bottom by digging. The metallic capping layer is under the mesh layer. The plurality of cavities is covered by the metallic capping layer with high reflective metal such as silver (Ag) or aluminum (Al) in order to generate mirror reflection effect on the mesh substrate.

According to the characteristics described above, the present invention proposes a method of fabricating a light emitting diode, with the steps of: forming a pn-junction semiconductor layer on the substrate; forming a mesh substrate disposed under the pn-junction semiconductor layer; and forming a thermal dissipation layer disposed under the mesh substrate.

The step of forming the mesh substrate further comprises steps of: digging a plurality of cavities on the bottom of the substrate under the pn-junction semiconductor layer by using LASER to form the mesh substrate and arranged the plurality of cavities in matrix to form the mesh structure; and covering a metal layer on the surface of the plurality of cavities by means of physical vapor deposition (PVD) or chemical vapor deposition (CVD) to form a plurality of metallic cavities.

The light emitting diode produced by above fabrication has a mesh substrate with a mesh texture structure thereby generate multiple-reflection to increase luminous brightness. In addition, the thermal dissipation layer disposed under the mesh substrate by means of coating or electroplating. Because metal with high thermal conductivity is used in the thermal dissipation layer, the heat that generated by photoelectric effect can be appropriately dissipated and the internal junction temperature can be decreased. Therefore, the emitting efficiency and lifetime of the LED are both increased.

The present invention via LASER scribing method is used to build up a texture on the backside of the sapphire substrate. High reflectivity and thermal conductivity metals are thereafter deposited or coated onto the mesh substrate to enhance the emitting efficiency. Meanwhile, junction temperature will be decreased and thermal effect, a negative effect to light emitting diode, will be eased.

### BRIEF DESCRIPTION OF THE DRAWINGS

The invention will be described according to the appended drawings in which:

FIG. 1A is a solid diagram of a light emitting diode according to the present invention;

FIG. 1B is a cross sectional view of a light emitting diode according to the present invention;

FIG. 2A is a flow chart showing a process for fabricating a light emitting diode according to the embodiment of the present invention;

FIG. 2B is a cross sectional view showing, in the order of process, a method of fabrication of the light emitting diode according to the embodiment of the present invention; and

FIG. 3 is a top view photograph illustrating the mesh substrate of the light emitting diode according to the present invention.

### DETAILED DESCRIPTION OF THE INVENTION

The present invention hereby discloses a light emitting diode and fabrication thereof. To thoughtfully understand the present invention for the readers, it will be described in detail below what the procedures and the components. Obviously, practice of the present invention does not to be place restrictions on the light emitting diode and fabrication thereof that those of ordinary skill in the art can understand the partial detail. On the other hand, the procedures or the components which are known to all do not be specified in this application, to avoid causing not necessary limitation on the present invention. Best model of the present invention will be specified below, however except those detailed descriptions, the present invention also can be use widely within other embodiments, otherwise scope of the present invention does not be restricted, and it will be principle to below claims.

The present invention is fabricated after manufacturing a conventional horizontal type light emitting diode. The conventional light emitting diode includes a thinned out sapphire substrate (i.e. aluminum oxide, Al₂O₃) with thickness about 100 μm. An epitaxial layer is then formed by growing indium gallium nitride (InGaN) with thickness about 4 μm to 5 μm on the sapphire substrate by epitaxy, wherein the epitaxial layer has different dopant light-emitting quantum well layers. Finally, a mesa structure is formed by conventional lithographic and etching processes and electrodes are plated thereon.

The present invention can be fabricated on conventional light emitting diodes or all the horizontal type light emitting diodes. The structure of the present invention comprises three main parts. The first part is to scribe stripe-like or criss-cross square-type cavities, which are spread on the backside of the LED chip, by LASER, wherein the backside of the LED chip is sapphire substrate. The cavities with width and depth range to several tens of micrometers and pitch ranged from several to several tens of micrometers. The second part is to fabricate a reflective layer with high thermal conductivity by physical vapor deposition (PVD) or chemical vapor deposition (CVD). Metals that can reflect major wave band and with high thermal conductivities are preferred to form the reflective layer. Of these metals silver or aluminum is preferred. The third part is to plate high thermal conductivity metals, copper or silver is preferred, on the thermal dissipation layer by coating or electroplating to increase its thickness and cover the cavities.

In practical fabrication of the present invention, linear cavities, which are parallel to the chip, are scribed on the sapphire substrate via LASER, wherein the linear cavities are about 10 μm width, about 30 μm depth, and the pitch ranged about 30 μm. Then sapphire substrate is scribed repeatedly on the direction vertical to the chip to form a checkered pattern. The reflective layer is thereafter formed by using E-gun evaporator by plating silver or aluminum with thickness about 0.5 μm Meanwhile, the grid-like reflective layer is disposed under the sapphire substrate to reflect lights more efficiently. Finally, the thermal dissipation layer is formed by plating copper (about 30 μm to 50 μm) under the substrate. Blue light LED is used as main embodiment of the present invention. The invention is to form the mesh texture structure on the backside of the sapphire substrate then deposit metal with high reflectivity and high thermal conductivity to enhance reflectivity and emitting efficiency. Then, a metal layer is deposited under the sapphire substrate to improve thermal conductivity coefficient thereby improve thermal dissipating effect and reduce internal thermal resistance of the LED and reduce temperature in quantum well. Therefore, the present invention discloses a structure fabrication which can increase emitting efficiency and decrease thermal effect.

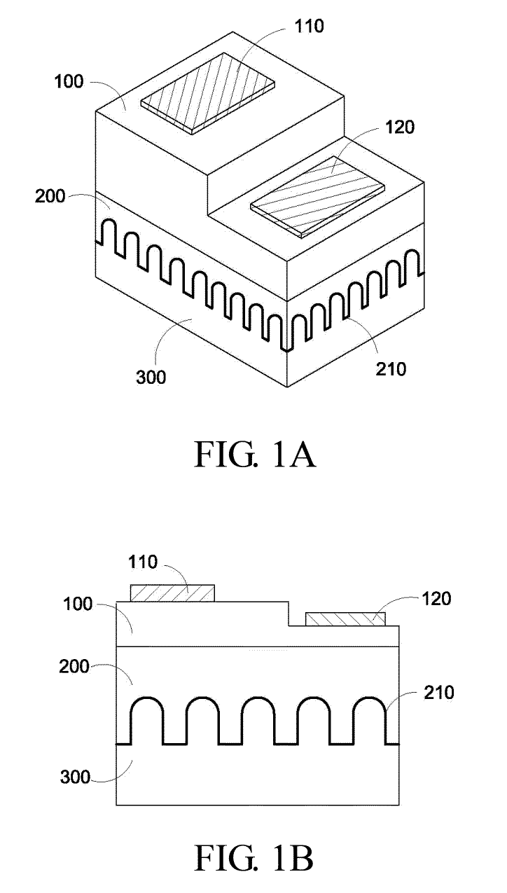

FIG. 1A and FIG. 1B show a light emitting diode according to the present invention, wherein FIG. 1A is a solid diagram and FIG. 1B is a cross sectional view. The LED comprises a pn-junction semiconductor layer 100, a mesh substrate 200, and a thermal dissipation layer 300. The pn-junction semiconductor layer 100 comprises a p-type electrode 110 and an n-type electrode 120 arranged in parallel on the pn-junction semiconductor layer 100. The material of the pn-junction semiconductor layer 100 is gallium nitride (GaN) or indium gallium nitride (InGaN). The thickness of the mesh substrate 200, which is under the pn-junction semiconductor layer 100 and caused multiple-reflection, is greater than or equal to one-sixth of the thickness of light-emitting wavelength. Moreover, the thermal dissipation layer 300 is disposed under the mesh substrate 200 to dissipate heat generated by emitted light. The composition of the thermal dissipation layer 300 is copper (Cu) which has very high thermal conductivity.

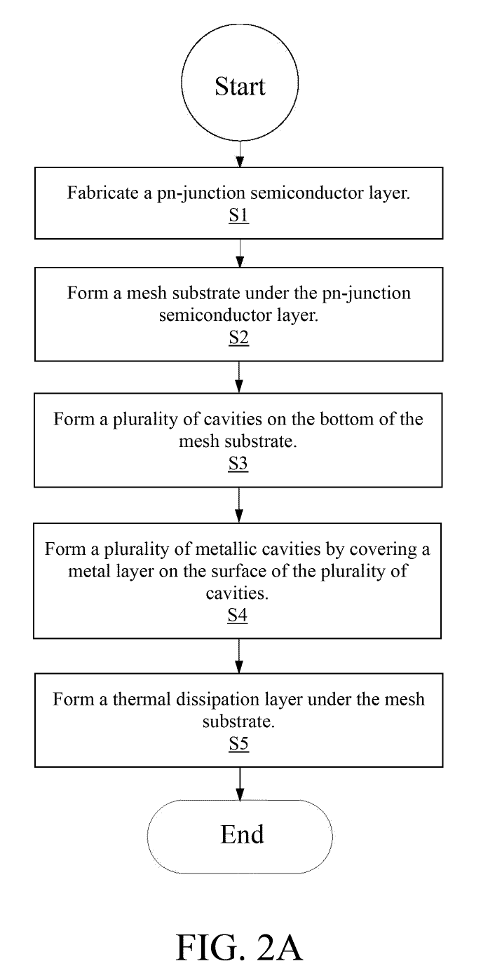

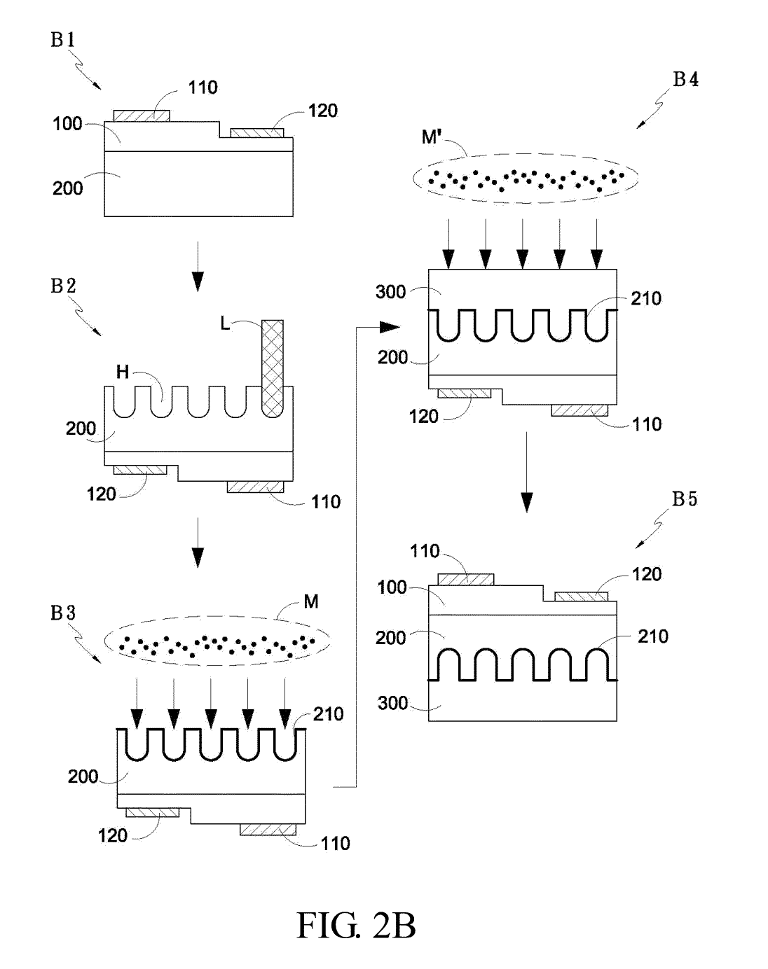

The present invention is to be fabricated after manufacturing a conventional horizontal type light emitting diode. The conventional light emitting diode includes a thinned out sapphire substrate (i.e. aluminum oxide, Al₂O₃) with thickness about 100 μm. An epitaxial layer is then formed by growing indium gallium nitride (InGaN) with thickness about 4 μm to 5 μm on the sapphire substrate by epitaxy, wherein the epitaxial layer has different dopant light-emitting quantum well layers. Finally, the mesa structure is formed by conventional lithographic and etching processes and the p-type electrode and the n-type electrode are plated thereon. The present invention can be fabricated by using LASER cutting and vapor deposition on the conventional light emitting diode. The method for fabricating the light emitting diode includes steps of: forming the pn-junction semiconductor layer on the substrate; forming the mesh substrate disposed under the pn-junction semiconductor layer; and forming the thermal dissipation layer disposed under the mesh substrate. The step of forming the mesh substrate further comprises steps of forming the mesh texture and covering the metal layer on the bottom surface of the mesh substrate. FIG. 2A is a flow chart showing a process for fabricating a light emitting diode according to the embodiment of the present invention.

Referring to FIG. 2A, step S1 is to form a pn-junction semiconductor layer. This step is the same as fabricating a conventional LED. Step S2 is to form a mesh substrate under the pn-junction semiconductor layer. Step S3 is to form a plurality of cavities on the bottom of the mesh substrate by using LASER. Step S4 is to cover a metal layer on the plurality of cavities by means of physical vapor deposition (PVD) or chemical vapor deposition (CVD) to form a plurality of metallic cavities and, moreover, fill the bottom surface of the mesh substrate. Step S5 is to form a metallic thermal dissipation layer under the mesh substrate to dissipate heat generated by emitted light, wherein the thermal dissipation layer can also be made by ceramic.

FIG. 2B is a cross sectional view showing, in the order of process, a method of fabrication of the light emitting diode according to the embodiment of the present invention. Referring to FIG. 2B, step B1 shows the light emitting diode processed after step S1. Apparently the mesh substrate 200 haven't process step S2 because there is no mesh texture thereunder. Step B2 shows the light emitting diode turned 180° in order to process step S3. The plurality of cavities H is formed on the bottom of the mesh substrate 200 by LASER beam L. Step B3 illustrates step S4 of forming a metallic capping layer 210 by depositing metal M on the plurality of cavities H by using E-gun evaporator by means of physical vapor deposition (PVD) or chemical vapor deposition (CVD), wherein, metals with high reflectivity such as silver (Ag) or aluminum (Al) is preferred. Step B4 shows the step of forming a metallic thermal dissipation layer 300 by coating metal M′ on the metallic capping layer 210, wherein the metallic capping layer 210 is on the mesh substrate 200. Copper (Cu) which has very high thermal conductivity is preferred for the metal M′. Finally, Step B5 shows the light emitting diode fabricated from step S1 to step S5, wherein the structure of the light emitting diode is the same as which the light emitting diode shown in FIG. 1B.

The metallic capping layer 210 described above can be formed by not only chemical vapor deposition (CVD) but also high density plasma chemical vapor deposition (HDP-CVD). Similarly, the metallic dissipation layer 300 can be formed by not only electroplating or coating but also by physical vapor deposition (PVD) or chemical vapor deposition (CVD).

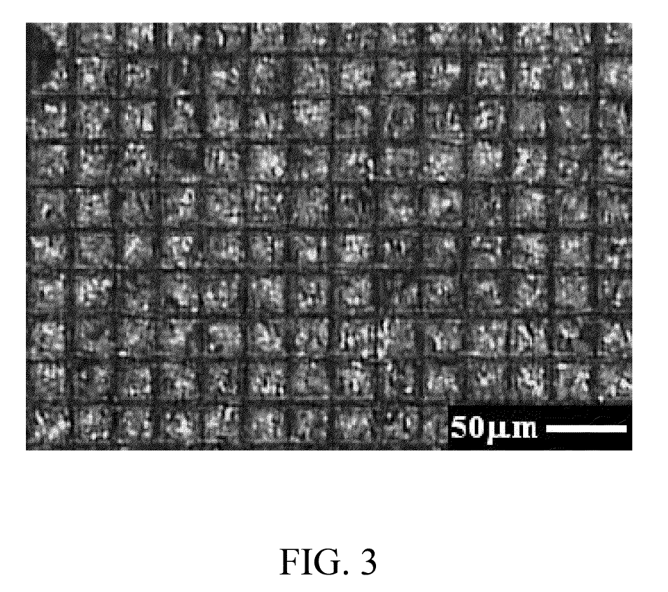

In accordance with the preferred embodiment of the present invention, the metallic capping layer 210 is formed by using E-gun evaporator by physical evaporation or chemical evaporation. Via step S3 to step S4, the mesh texture is built up on the bottom of the mesh substrate 200. A plurality of cavities H is formed by digging in array by LASER beam L. Then the metallic capping layer 210 covered the plurality of cavities H can increase photoreflectance of the mesh substrate 200. FIG. 3 is a top view photograph illustrating the plurality of cavities H with checker-patterned mesh texture. Since the mesh texture disposed under the substrate, the light extraction efficiency will be increased. In addition, the thermal dissipation layer can dissipate heat generated by emitted light in quantum well, and therefore decrease the LED temperature and prolong the LED lifetime.

The above-described embodiment of the present invention is intended to be illustrative only. Numerous alternative embodiments may be devised by persons skilled in the art without departing from the scope of the following claims.

What is claimed is:

1. A light emitting diode comprising:
a pn-junction semiconductor layer comprising a p-type electrode and an n-type electrode arranged in parallel on said pn-junction semiconductor layer;
a mesh substrate disposed under said pn-junction semiconductor layer; and
a thermal dissipation layer under said mesh substrate to dissipate heat generated by emitted light and change lighting direction.

2. The light emitting diode according to claim 1, wherein the material of said pn-junction semiconductor is gallium nitride (GaN).

3. The light emitting diode according to claim 1, wherein the material of said pn-junction semiconductor is indium gallium nitride (InGaN).

4. The light emitting diode according to claim 1, wherein thickness of said mesh substrate is greater than or equal to one-sixth of thickness of light-emitting wavelength.

5. The light emitting diode according to claim 1, wherein said mesh substrate further comprising a mesh layer with a plurality of cavities spread on the bottom, and a metallic capping layer, wherein said metallic capping layer is under said mesh layer and covering or filling said plurality of cavities to form said plurality of metallic cavities.

6. The light emitting diode according to claim 5, wherein said plurality of cavities are arranged in matrix.

7. The light emitting diode according to claim 5, wherein said mesh layer is sapphire.

8. The light emitting diode according to claim 5, wherein said mesh layer is made of transparent medium such as Si, LaAlO₃, LiGaO₂, GaN, SiC or diamond.

9. The light emitting diode according to claim 5, wherein said metallic capping layer is silver (Ag).

10. The light emitting diode according to claim 5, wherein said metallic capping layer is aluminum (Al).

11. The light emitting diode according to claim 1, wherein said thermal dissipation layer is made of metallic or ceramic materials, wherein said metallic materials including copper (Cu).

12. A method for fabricating a light emitting diode comprising the steps of:
forming a pn-junction semiconductor layer on the substrate;
forming a mesh substrate disposed under the pn-junction semiconductor layer; and
forming a thermal dissipation layer disposed under the mesh substrate.

13. The method according to claim 12, wherein the material of said pn-junction semiconductor is gallium nitride (GaN).

14. The method according to claim 12, wherein the material of said pn-junction semiconductor is gallium nitride (GaN).

15. The method according to claim 12, wherein said thermal dissipation layer is copper (Cu).

16. The method according to claim 12, wherein said step of thermal dissipating is forming said thermal dissipation layer by means of coating or physical vapor deposition (PVD).

17. The method according to claim 12, wherein said step of thermal dissipating is forming said thermal dissipation layer by means of electroplating.

18. The method according to claim 12, wherein said mesh substrate is sapphire.

19. The method according to claim 12, wherein said mesh substrate is made of transparent medium such as Si, LaAlO₃, LiGaO₂, GaN, SiC, or diamond.

20. The method according to claim 12, wherein a method for manufacturing said mesh substrate further comprising the steps of:
forming a mesh texture by digging a plurality of cavities on the bottom of said substrate; and
forming a plurality of metallic cavities by covering or filling a metal layer on the bottom surface of said mesh substrate.

21. The method according to claim 20, wherein said plurality of cavities are arranged in matrix.

22. The method according to claim 20, wherein said step of forming said mesh texture is etching said plurality of cavities on the bottom of said substrate by using LASER.

23. The method according to claim 20, wherein said metal is silver (Ag).

24. The method according to claim 20, wherein said metal is aluminum (Al).

25. The method according to claim 20, wherein said step of forming a plurality of metallic cavities by covering or filling a metal layer is by means of physical vapor deposition (PVD).

26. The method according to claim 20, wherein said step of forming a plurality of metallic cavities by covering or filling a metal layer is by means of chemical vapor deposition (CVD).

27. The method according to claim 20, wherein said step of forming a plurality of metallic cavities by covering or filling a metal layer is by means of high density plasma chemical vapor deposition (HDP-CVD).
